(19) United States
(12) Patent Application Publication
(10) Pub. No.: US 2016/0351493 A1
(43) Pub. Date: Dec. 1, 2016

(54) SEMICONDUCTOR DEVICE AND MANUFACTURING METHOD FOR THE SAME

(71) Applicant: MACRONIX International Co., Ltd., Hsinchu (TW)

(72) Inventors: Chien-Lan Chiu, Hsinchu (TW); Yung-Tai Hung, Hsinchu (TW); Chin-Ta Su, Hsinchu (TW); Tuung Luoh, Hsinchu (TW)

(21) Appl. No.: 14/723,076

(22) Filed: May 27, 2015

(51) Int. Cl. H01L 23/522; H01L 21/768; H01L 23/532

(52) U.S. Cl. CPC H01L 23/5226; H01L 23/5329; H01L 21/76802; H01L 21/76843

(57) ABSTRACT

A semiconductor device is provided, which includes a first conductive layer disposed on a substrate, a dielectric layer with at least an opening disposed on the first conductive layer, and a plurality of plugs filling up the openings. At least a portion of the dielectric layer adjacent to the openings is Si-rich, and each of the plugs includes a second conductive layer surrounded by a barrier layer.

### BACKGROUND OF THE INVENTION

1. Field of the Invention

The present invention generally relates to a semiconductor technology, and more particularly to a semiconductor device and manufacturing method for the same.

2. Description of Related Art

In a typical semiconductor device fabrication, conductive plugs such as vias or contacts are usually provided in dielectric layer to connect the adjacent horizontal metal layers. In conventional process, oxygen atom in a dielectric layer may react with Ti in a barrier layer, thus reduces adhesion ability of the barrier layer, causing voids between a bottom of the plug and a conductive layer, and the reliability and performance of the device are accordingly affected.

### SUMMARY OF THE INVENTION

The present invention provides a semiconductor device and a manufacturing method for the same, in which a void-free conductive plug can be easily formed with the method of the invention.

The present invention provides a semiconductor device including a first conductive layer disposed on a substrate, a dielectric layer with at least an opening disposed on the first conductive layer, and a plurality of plugs filling up the openings. At least a portion of the dielectric layer adjacent to the openings is Si-rich, and each of the plugs includes a second conductive layer surrounded by a barrier layer.

According to an embodiment of the present invention, the dielectric layer includes SiOₓ, and x ranges from 0.2 to 2.0.

According to an embodiment of the present invention, a refractive index at 248 nm of the dielectric layer ranges from 1.52 to 1.55.

According to an embodiment of the present invention, an O¹⁸ concentration of the dielectric layer is less than 1.09×10²⁰ atom/cm³.

According to an embodiment of the present invention, an O¹⁸ concentration of a bottom of the dielectric layer is lower than an O¹⁸ concentration of a top of the dielectric layer.

According to an embodiment of the present invention, the O¹⁸ concentration of the dielectric layer has a gradient distribution.

According to an embodiment of the present invention, the dielectric layer has an upper layer and a lower layer, and an O¹⁸ concentration of the lower layer is lower than an O¹⁸ concentration of the upper layer.

According to an embodiment of the present invention, an O¹⁸ concentration of the dielectric layer adjacent to the openings is lower than an O¹⁸ concentration of the dielectric layer at the middle point of two neighbouring openings.

According to an embodiment of the present invention, the O¹⁸ concentration of the dielectric layer has a gradient distribution.

According to an embodiment of the present invention, the dielectric layer has an inner layer adjacent to each of the openings and an outer layer not adjacent to the openings, and an O¹⁸ concentration of the inner layer is lower than an O¹⁸ concentration of the outer layer.

The present invention further provides a manufacturing method for a semiconductor device. A substrate having a first conductive layer is provided, and a dielectric layer is formed on the first conductive layer. A plurality of openings through the dielectric layer is formed, exposing the first conductive layer. At least a portion of the dielectric layer adjacent to the openings is Si-rich. A plug is formed in each of the openings, and each of the plugs includes a second conductive layer surrounded by a barrier layer.

According to an embodiment of the present invention, the dielectric layer includes SiOₓ, and x ranges from 0.2 to 2.0.

According to an embodiment of the present invention, a refractive index at 248 nm of the dielectric layer ranges from 1.52 to 1.55.

According to an embodiment of the present invention, an O¹⁸ concentration of the dielectric layer is less than 1.09×10²⁰ atom/cm³.

According to an embodiment of the present invention, an O¹⁸ concentration of a bottom of the dielectric layer is lower than an O¹⁸ concentration of a top of the dielectric layer.

According to an embodiment of the present invention, the O¹⁸ concentration of the dielectric layer has a gradient distribution.

According to an embodiment of the present invention, an upper layer and a lower layer are foimed, and an O¹⁸ concentration of the lower layer is lower than an O¹⁸ concentration of the upper layer.

According to an embodiment of the present invention, an O¹⁸ concentration of the dielectric layer adjacent to the openings is lower than an O¹⁸ concentration of the dielectric layer at the middle point of two neighbouring openings.

According to an embodiment of the present invention, the O¹⁸ concentration of the dielectric layer has a gradient distribution.

According to an embodiment of the present invention, an inner layer adjacent to each of the openings and an outer layer not adjacent to the openings are formed, and an O¹⁸ concentration of the inner layer is lower than an O¹⁸ concentration of the outer layer.

In view of the above, since a Si-rich dielectric layer is used as dielectric layer, Ti in a barrier layer of a conductive plug is hard to be oxidized. In such manner, the adhesion ability of the barrier layer may be maintained, avoiding voids occurring between a bottom of the plug and a conductive layer. Therefore, a void-free conductive plug can be easily formed, and the reliability and performance of the device can be accordingly enhanced.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are schematic cross-sectional views of a method of forming a semiconductor device according to an embodiment of the present invention.

FIG. 2 is a schematic cross-sectional view of a second embodiment of the present invention.

FIG. 3 is a schematic cross-sectional view of a third embodiment of the present invention.

FIG. 4 is a schematic cross-sectional view of a fourth embodiment of the present invention.

FIG. 5 is a schematic cross-sectional view of a fifth embodiment of the present invention.

### DESCRIPTION OF THE EMBODIMENTS

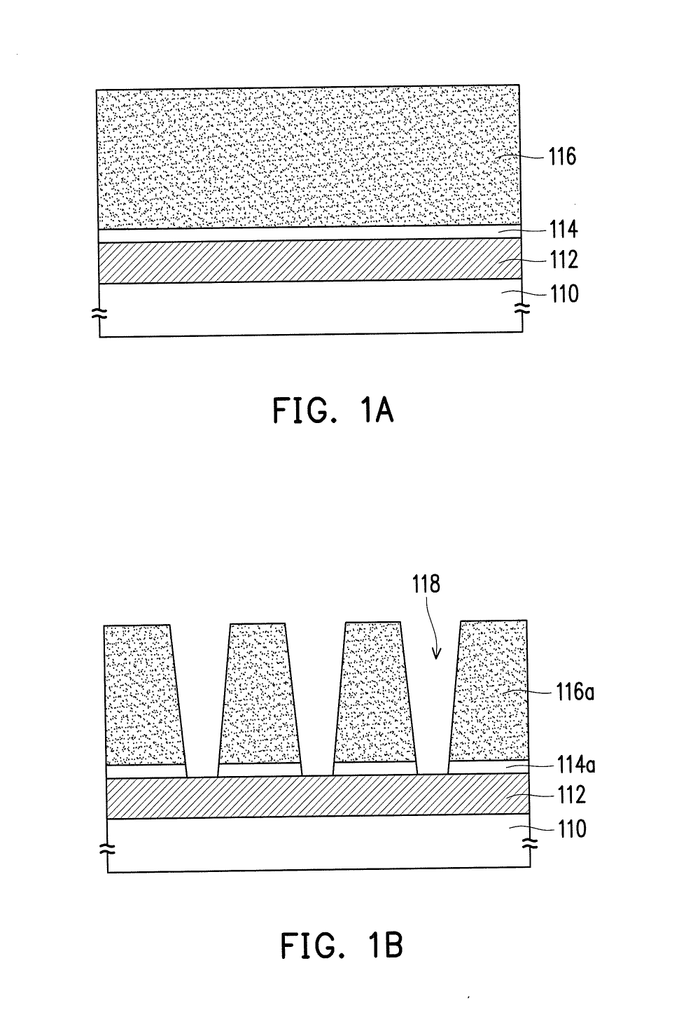

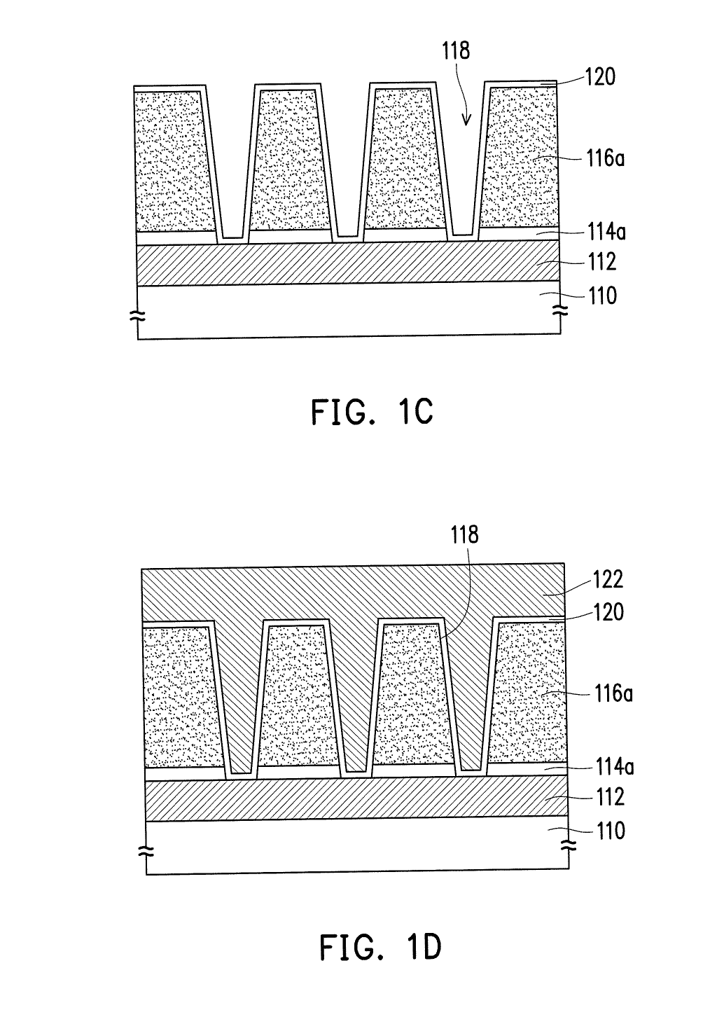

Reference will now be made in detail to the present preferred embodiments of the invention, examples of which are illustrated in the accompanying drawings. Wherever possible, the same or like reference numbers are used in the drawings and the description to refer to the same or like parts. For example, reference number 110 in FIG. 1A to FIG. 1E refers to a substrate, while reference number 210 in FIG. 2 also refers to a substrate.

FIG. 1A to FIG. 1E are schematic cross-sectional views of a method of fowling a semiconductor device according to an embodiment of the present invention.

Referring to FIG. 1A, a first conductive layer 112 and a cap layer 114 are formed on a substrate 110. The substrate 110 may include a semiconductor material, an insulator material, a conductor material, or any combination of the foregoing materials. The material of the substrate 110 is a material composed of at least one selected from a group consisting of Si, Ge, SiGe, GaP, GaAs, SiC, SiGeC, InAs, and InP, or any physical structure suitable for a fabricating process of the invention, for example. The substrate 110 includes a single-layer structure or a multi-layer structure. In addition, a silicon on insulator (SOI) substrate may be used as the substrate 110. The substrate 110 is silicon or silicon germanium, for example. The first conductive layer 112 can be a metal layer including copper, alloy of copper, or a combination thereof, the forming method thereof includes performing a deposition process, such as chemical vapour deposition (CVD), physical vapour deposition (PVD) or atomic layer deposition (ALD), or a sputtering method. The cap layer 114 can be an insulating layer including SiN, SiCN, SiCO, or SiON, and the cap layer 114 may be formed by, for example, a chemical vapor deposition method.

Still referring to FIG. 1A, a dielectric layer 116 is formed on the cap layer 114. A thickness of the dielectric layer 116 ranges from 100 to 1200 nm, for example. The dielectric layer 116 may be a Si-rich dielectric layer including SiOₓ, and x ranges from 0.2 to 2.0. In an embodiment, x ranges from 0.4 to 1.5. A refractive index at 248 nm of the dielectric layer 116 ranges from 1.52 to 1.55. In a dielectric layer, a Si concentration is inversely related to an O¹⁸ concentration. Thus, an O¹⁸ concentration of the dielectric layer 116, which is Si-rich, is less than 1.09×10²⁰ atom/cm³, wherein the O¹⁸ concentration of the dielectric layer 116 is measured by secondary ion mass spectroscopy (SIMS). In an embodiment, the O¹⁸ concentration of the dielectric layer 116 ranges from 0.5×10²⁰ to 1.09×10²⁰ atom/cm³. The method of forming the dielectric layer 116 includes performing a deposition process, such as CVD, PVD, or ALD. In an embodiment, the dielectric layer 116 is formed by plasma enhanced chemical vapor deposition (PECVD) process. In an embodiment, when a PECVD process is conducted, the high-frequency power ranges from 150 W to 900 W, the chamber pressure ranges from 1 ton to 10 torr, the flow rate of SiH₄ ranges from 150 to 900 sccm, and a flow rate of N₂O ranges from 500 sccm to 14000 sccm. Gases used during the implementation of the PECVD process further include noble gases, for example, Ar or He. A flow rate of noble gases during the implementation of the PECVD process ranges from 500 sccm to 14000 sccm.

Referring to FIG. 1B, a plurality of openings 118 are formed through the dielectric layer 116a and the cap layer 114a, and exposing a portion of the first conductive layer 112. According to an embodiment of the present invention, the method of forming the openings 118 in the dielectric layer 116a includes, for example, forming a patterned photoresist layer (not shown) over the dielectric layer 116; and etching the dielectric layer 116 using the patterned photoresist layer as an etching mask to remove a portion of the dielectric layer 116 and a portion of the cap layer 114 to form the openings 118.

A critical dimension ratio (CD ratio) of bottom to middle (Bot/Mid) or bottom to top (Bot/Top) of the openings 118 ranges from 0.5 to 1. In this embodiment, each opening 118 has a tilted sidewall and is made with a wide top and a narrow bottom, as shown in FIG. 1B, but the present is not limited thereto. In another embodiment, each opening 118 can be shaped in trapezoid with narrow top and wide bottom or can have a substantially vertical sidewall.

Referring to FIG. 1C, a barrier layer 120 is formed on the substrate 110. In an embodiment, the barrier layer 120 is a conformal layer covering the dielectric layer 116a and the openings 118. The barrier layer 120 can be a single layer or a multi-layer including two or more layers. The barrier layer 120 includes refractory metal, refractory metal nitride or a combination thereof. For example, the barrier layer 120 includes titanium (Ti), titanium nitride (TiN), tantalum (Ta), tantalum nitride (TaN), tungsten nitride (WN) or a combination thereof. The barrier layer 120 can be further doped with Cu, Al, W, Co to prevent oxidization. The method of forming the barrier layer 120 includes performing a deposition process, such as CVD, PVD or ALD.

Referring to FIG. 1D and 1E, a second conductive material layer 122 is formed on the substrate, filling in each opening 118. The second conductive material layer 122 includes metal (such as tungsten or aluminium) or alloy (such as aluminum-copper alloy) and the forming method thereof includes performing a deposition process, such as CVD, PVD or ALD, followed by a flattening process such CMP process. After the second conductive material layer 122 is formed, performing a flattening process such as a chemical mechanical polishing (CMP) process to remove at least a part of the second conductive material layer 122 and a part of the barrier layer 120, forming a plug 124 in each opening 118. Each plug 124 includes a barrier layer 120a and a second conductive layer 122a.

The semiconductor device of the present invention is illustrated with reference to FIG. 1E in the following. As shown in FIG. 1E, the semiconductor device of the invention includes a first conductive layer 112, a Si-rich dielectric layer 116a with at least an opening 118, and a plurality of plugs 124. The first conductive layer 112 is disposed on a substrate 110. The Si-rich dielectric layer 116a with at least an opening 118 is disposed on the first conductive layer 112. The plugs 124 fill up the openings 118, and each of the plugs 124 includes a second conductive layer 122a surrounded by a barrier layer 120a.

In the aforementioned embodiment, the dielectric layer is a Si-rich dielectric layer. In the dielectric layer, a Si concentration is inversely related to an O¹⁸ concentration. Thus in the Si-rich dielectric layer, the O¹⁸ concentration is less than 1.09×10²⁰ atom/cm³ (measured by SIMS).

In other embodiments of the invention, the dielectric layer can be partially Si-rich, wherein at least a portion of the dielectric layer adjacent to the openings is Si-rich. For example, the Si in the dielectric layer can have a gradient distribution. Since in the dielectric layer, a Si concentration is inversely related to an O¹⁸ concentration, the O¹⁸ concentration in the dielectric layer can accordingly have a gradient distribution inversed to the gradient distribution of Si. In still other embodiments of the invention, the dielectric can be a multi layer including two or more layers, and at least one of the layers can be Si-rich. Accordingly, one of the layers can have an O¹⁸ concentration less than 1.09∴10²⁰ atom/cm³.

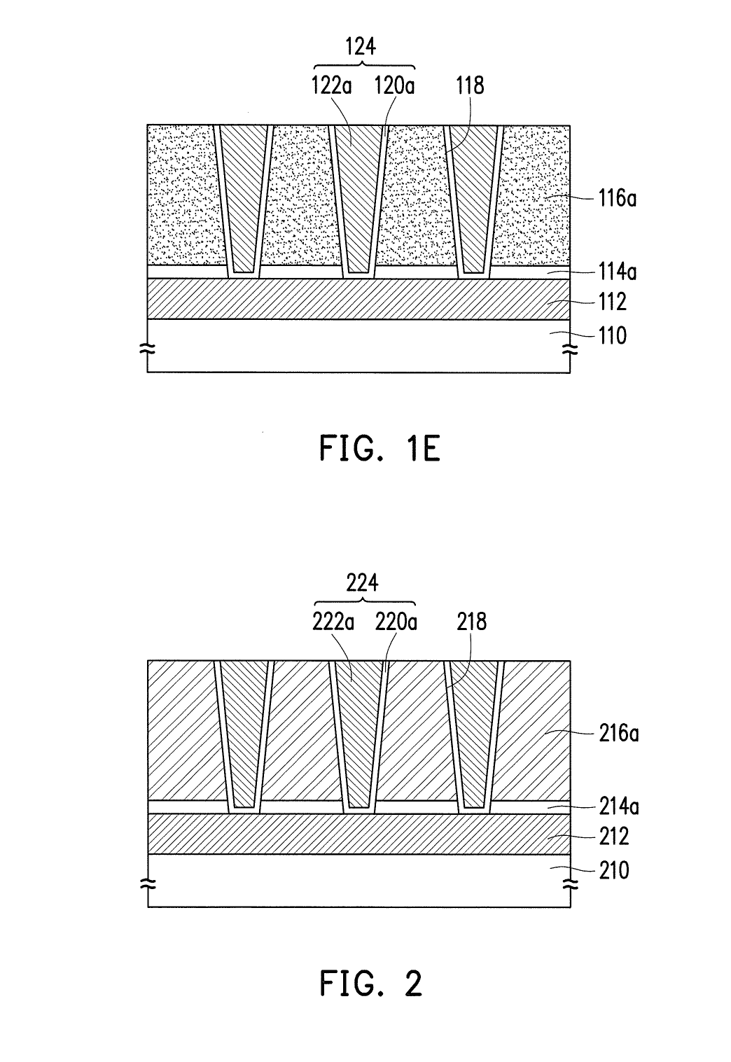

FIG. 2 is a schematic cross-sectional view of a second embodiment of the present invention; and FIG. 3 is a schematic cross-sectional view of a third embodiment of the present invention.

Referring to FIG. 2 and FIG. 3, the O¹⁸ concentration of the dielectric layer of the invention can have a gradient distribution along vertical direction (FIG. 2) or horizontal direction (FIG. 3).

Referring to FIG. 2, when the O¹⁸ concentration of the dielectric layer 216a has a gradient distribution along vertical direction, the O¹⁸ concentration of a bottom of the dielectric layer 216a is lower than the O¹⁸ concentration of a top of the dielectric layer 216a. That is, the Si concentration of a bottom of the dielectric layer 216a is higher than the Si concentration of a top of the dielectric layer 216a. At the bottom of the dielectric layer 216a, the O¹⁸ concentration is less than 1.09×10²⁰ atom/cm³. In an embodiment, the O¹⁸ concentration at the bottom of the dielectric layer 216a ranges from 0.5×10²⁰ to 1.09'10²⁰ atom/cm³. Refractive index at 248 nm at the bottom of the dielectric layer 216a ranges from 1.52 to 1.55. SiOₓ included at the bottom of the dielectric layer 216a has an x ranges from 0.2 to 2.0. In another embodiment, x ranges from 0.4 to 1.5.

Referring to FIG. 3, when the O¹⁸ concentration of the dielectric layer 316a has a gradient distribution along horizontal direction, the O¹⁸ concentration of the dielectric layer 316a adjacent to the openings 318 is lower than the O¹⁸ concentration of the dielectric layer 316a at the middle point of two neighbouring openings 318. That is, the Si concentration of the dielectric layer 316a adjacent to the openings 318 is higher than the Si concentration of the dielectric layer 316a at the middle point of two neighbouring openings 318. In the dielectric layer 316a adjacent to the openings 318, the O¹⁸ concentration of the dielectric layer 316a adjacent to the openings 318 is less than 1.09×10²⁰ atom/cm³. In an embodiment, the O¹⁸ concentration in the dielectric layer 316a adjacent to the openings 318 ranges from 0.5×10²⁰ to 1.09×10²⁰ atom/cm³. Refractive index at 248 nm in the dielectric layer 316a adjacent to the openings 318 ranges from 1.52 to 1.55. SiOₓ included in the dielectric layer 316a adjacent to the openings 318 has an x ranges from 0.2 to 2.0. In another embodiment, x ranges from 0.4 to 1.5.

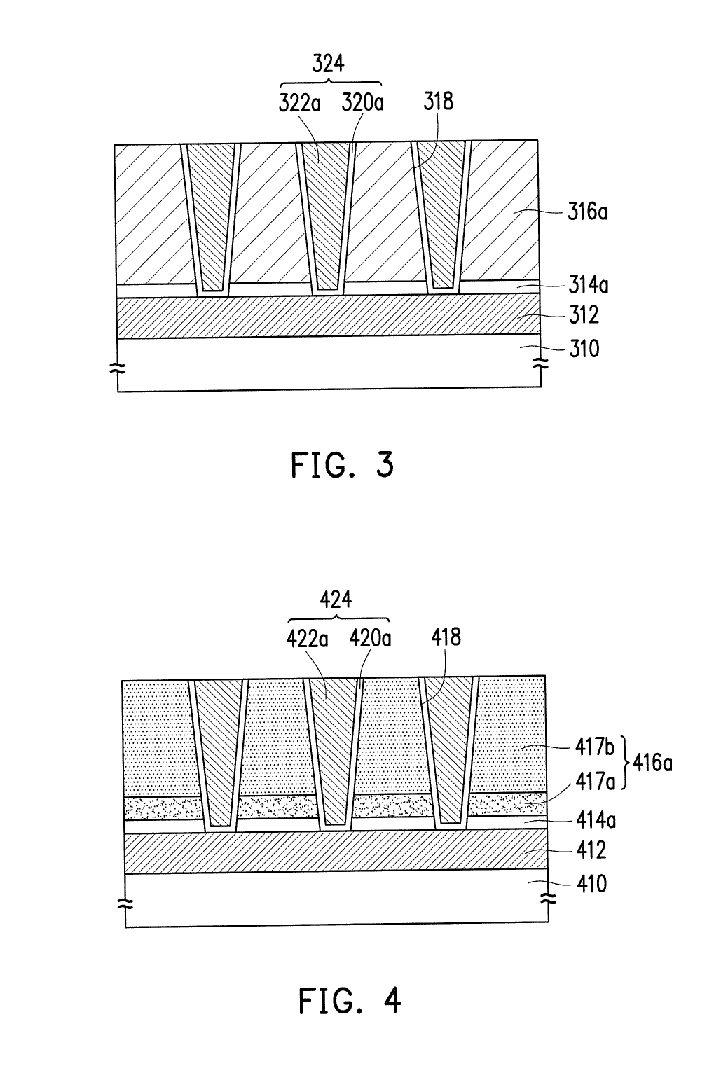

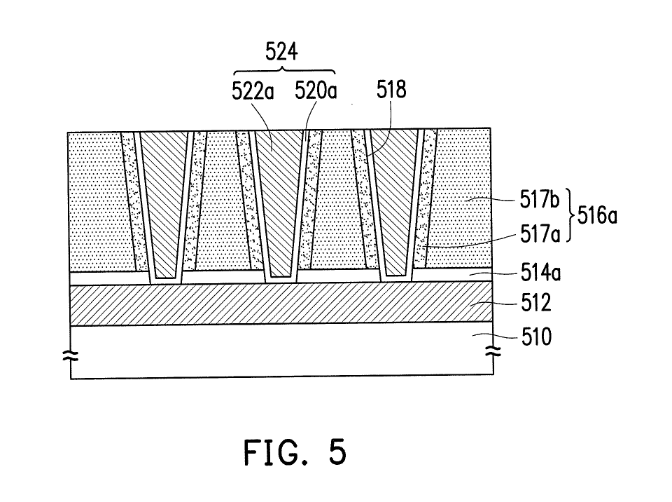

FIG. 4 is a schematic cross-sectional view of a fourth embodiment of the present invention; and FIG. 5 is a schematic cross-sectional view of a fifth embodiment of the present invention.

Referring to FIG. 4 and FIG. 5, the dielectric layer of the invention can be a multi-layer including two or more layers.

Referring to FIG. 4, the dielectric layer 416a has a lower layer 417a and an upper layer 417b, and an O¹⁸ concentration of the lower layer 417a is lower than an O¹⁸ concentration of the upper layer 417b. That is, the Si concentration of the lower layer 417a is higher than the Si concentration of the upper layer 417b. The O¹⁸ concentration of the lower layer 417a is less than 1.09×10²⁰ atom/cm³. In an embodiment, the O¹⁸ concentration of the lower layer 417a ranges from 0.5×10²⁰ to 1.09×10²⁰ atom/cm³. The lower layer 417a includes SiOₓ, and x ranges from 0.2 to 2.0. In another embodiment, x ranges from 0.4 to 1.5. Refractive index at 248 nm of the lower layer 417a ranges from 1.52 to 1.55. The O¹⁸ concentration of the upper layer 417b is more than 1.09×10²⁰ atom/cm³. In an embodiment, the O¹⁸ concentration of the upper layer 417b ranges from 1.09×10²⁰ to 1.5×10²⁰ atom/cm³. The upper layer 417b includes SiO_{y}, and y ranges from 1.6 to 2.0. Refractive index at 248 nm of the upper layer 417b ranges from 1.50 to 1.519.

Referring to FIG. 5, the dielectric layer 516a has an inner layer 517a adjacent to each of the openings 518 and an outer layer 157b not adjacent to the openings 518, and an O¹⁸ concentration of the inner layer 517a is lower than an O¹⁸ concentration of the outer layer 517b. That is, the Si concentration of the inner layer 517a is higher than the Si concentration of the outer layer 517b. The O¹⁸ concentration of the inner layer 517a is less than 1.09×10²⁰ atom/cm³. In an embodiment, the O¹⁸ concentration of the inner layer 517a ranges from 0.5×10²⁰ to 1.09×10²⁰ atom/cm³. The inner layer 517a includes SiOₓ, and x ranges from 0.2 to 2.0. In another embodiment, x ranges from 0.4 to 1.5. Refractive index at 248 nm of the inner layer 517a ranges from 1.52 to 1.55. The O¹⁸ concentration of the outer layer 517b is more than 1.09×10²⁰ atom/cm³. In an embodiment, the O¹⁸ concentration of the outer layer 517b ranges from 1.09×10²⁰ to 1.5×10²⁰ atom/cm³. The outer layer 517b includes SiO_{y}, and y ranges from 1.6 to 2.0. Refractive index at 248 nm of the outer layer 517b ranges from 1.50 to 1.519.

The semiconductor device of the present invention is illustrated with reference to FIG. 2 to FIG. 5 in the following. As shown in FIG. 2 to FIG. 5, the semiconductor device of the invention includes a first conductive layer, a dielectric layer with at least an opening, and a plurality of plugs. The first conductive layer is disposed on a substrate. The dielectric layer with at least an opening is disposed on the first conductive layer, wherein at least a portion of the dielectric layer adjacent to the openings is Si-rich. The plugs fill up the openings, and each of the plugs includes a second conductive layer surrounded by a barrier layer.

In summary, in the semiconductor device of the invention, since a Si-rich is used as inter metal dielectric layer, Ti in a barrier layer of a conductive plug is hard to be oxidized. In such manner, the adhesion ability of the barrier layer may be maintained, avoiding voids occurring between a bottom of the plug and a conductive layer. Therefore, a void-free conductive plug can be easily formed, and the reliability and performance of the device can be accordingly enhanced. Extra step is not required in the invention, and a void-free plug can be easily formed. In other words, the method of the invention is competitive, and process window is greater for mass production.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor device, comprising:
a first conductive layer, disposed on a substrate;
a dielectric layer with at least an opening, disposed on the first conductive layer, wherein at least a portion of the dielectric layer adjacent to the openings is Si-rich; and
a plurality of plugs, filling up the openings, and each of the plugs comprises a second conductive layer surrounded by a barrier layer.

2. The semiconductor device of claim 1, wherein the dielectric layer comprises SiOₓ and x ranges from 0.2 to 2.0.

3. The semiconductor device of claim 1, wherein a refractive index at 248 nm of the dielectric layer ranges from 1.52 to 1.55.

4. The semiconductor device of claim 1, wherein an O¹⁸ concentration of the dielectric layer is less than 1.09×10²⁰ atom/cm³.

5. The semiconductor device of claim 1, wherein an O¹⁸ concentration of a bottom of the dielectric layer is lower than an O¹⁸ concentration of a top of the dielectric layer.

6. The semiconductor device of claim 5, wherein the O¹⁸ concentration of the dielectric layer has a gradient distribution.

7. The semiconductor device of claim 5 wherein the dielectric layer has an upper layer and a lower layer, and an O¹⁸ concentration of the lower layer is lower than an O¹⁸ concentration of the upper layer.

8. The semiconductor device of claim 1, wherein an O¹⁸ concentration of the dielectric layer adjacent to the openings is lower than an O¹⁸ concentration of the dielectric layer at the middle point of two neighbouring openings.

9. The semiconductor device of claim 8, wherein the O¹⁸ concentration of the dielectric layer has a gradient distribution.

10. The semiconductor device of claim 8, wherein the dielectric layer has an inner layer adjacent to each of the openings and an outer layer not adjacent to the openings, and an O¹⁸ concentration of the inner layer is lower than an O¹⁸ concentration of the outer layer.

11. A manufacturing method for a semiconductor device, comprising:
providing a substrate having a first conductive layer, and forming a dielectric layer on the first conductive layer;
forming a plurality of openings through the dielectric layer and exposing the first conductive layer, wherein at least a portion of the dielectric layer adjacent to the openings is Si-rich; and
forming a plug in each of the openings, and each of the plugs comprises a second conductive layer surrounded by a barrier layer.

12. The manufacturing method of claim 11, wherein the dielectric layer comprises SiOₓ, and x ranges from 0.2 to 2.0.

13. The manufacturing method of claim 11, wherein a refractive index at 248 nm of the dielectric layer ranges from 1.52 to 1.55.

14. The manufacturing method of claim 11, wherein an O¹⁸ concentration of the dielectric layer is less than 1.09×10²⁰ atom/cm³.

15. The manufacturing method of claim 11, wherein forming the dielectric layer comprises forming a dielectric layer with an O¹⁸ concentration of a bottom of the dielectric layer lower than an O¹⁸ concentration of a top of the dielectric layer.

16. The manufacturing method of claim 15, wherein forming the dielectric layer comprises forming the dielectric layer with a gradient distribution of O¹⁸ concentration.

17. The manufacturing method of claim 15, wherein forming the dielectric layer comprises:
forming an upper layer and a lower layer, and an O¹⁸ concentration of the lower layer is lower than an O¹⁸ concentration of the upper layer.

18. The manufacturing method of claim 11, wherein forming the dielectric layer comprises forming a dielectric layer with an O¹⁸ concentration of the dielectric layer adjacent to the openings lower than an O¹⁸ concentration of the dielectric layer at the middle point of two neighbouring openings.

19. The manufacturing method of claim 18, wherein forming the dielectric layer comprises forming the dielectric layer with a gradient distribution of O¹⁸ concentration.

20. The manufacturing method of claim 18, wherein forming the dielectric layer comprises:
forming an inner layer adjacent to each of the openings and an outer layer not adjacent to the openings, and an O¹⁸ concentration of the inner layer is lower than an O¹⁸ concentration of the outer layer.
